(19) United States
(12) Patent Application Publication
(10) Pub. No.: US 2007/0215945 A1
(43) Pub. Date: Sep. 20, 2007

(54) LIGHT CONTROL DEVICE AND DISPLAY

(75) Inventors: Hiroyuki Tokunaga, Fujisawa-shi (JP); Makoto Koto, Palo Alto, CA (US)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/686,752

(22) Filed: Mar. 15, 2007

Related U.S. Application Data
(63) Continuation-in-part of application No. 11/683,483, filed on Mar. 8, 2007.

(30) Foreign Application Priority Data
Mar. 20, 2006 (JP) 2006-076842
Dec. 20, 2006 (JP) 2006-342579

(51) Int. Cl. H01L 27/12

(52) U.S. Cl. 257/347

(57) ABSTRACT

Provided is a light control device including: a thin film transistor; and a light control element including an electrode electrically connected to the thin film transistor, in which a semiconductor region of the thin film transistor and an pixel electrode are composed of the same semiconductor layer, and the same semiconductor layer is an amorphous oxide layer including at least one of In, Ga, and Zn.

This application is a continuation-in-part application of U.S. Ser. No. 11/683,483 filed on Mar. 8, 2007.

### BACKGROUND OF THE INVENTION

1. Field of the Invention

The present invention relates to a light control device including a thin film transistor using an oxide semiconductor, and a light control element having an electrode electrically connected to the thin film transistor; and to a display including the light control device.

2. Description of the Related Art

In recent years, flat panel displays (FPD's) have been put into practical use by the progress of a technique for a liquid crystal, electroluminescence (EL), and the like. Those FPD's are each driven by an active matrix circuit of a field effect thin film transistor (TFT) in which an amorphous silicon film or a polysilicon thin film arranged on a glass substrate is used for an active layer. Meanwhile, attempts have been made to use a resin substrate having a light weight and flexibility instead of a glass substrate in order to further reduce the thickness and weight of each of those FPD's, and improve the resistivity to breakage thereof. However, the production of a transistor using the above-mentioned silicon thin film requires a step of heating at a relatively high temperature, so it is generally difficult to directly form the silicon thin film on a resin substrate having low heat resistance.

As an approach to solve this difficulty, a technique of forming a semiconductor layer which can be formed at a low temperature has been reviewed. For example, Japanese Patent Application Laid-Open No. 2002-76356 discloses a technique of forming an oxide semiconductor thin film made of ZnO as a main component. Further, Japanese Patent Publication No. H01-042146 discloses a display device for generally displaying an image in which a semiconductor layer and a pixel electrode layer are formed of different materials.

In general, in order to secure a charge storage property for writing into the pixel electrode layer, a storage capacitor is formed to be electrically connected in parallel with a pixel. A material used for forming an electrode layer (storage capacitor electrode layer) of the storage capacitor is also formed of a material different from the materials of a semiconductor layer and a pixel.

The storage capacitor electrode layer is generally formed using a gate wiring, a metal wiring provided on an upper layer, or the like, and the steps and structure for formation of the storage capacitor electrode layer may be complicated.

Japanese Patent No. 3,769,389 proposes, for simplification of the steps, a technique of forming a storage capacitor portion in such a manner that a semiconductor layer is extended to the storage capacitor portion, high concentration impurity doping is performed to lower the resistance, and a gate insulating layer and a gate electrode are formed thereon in the stated order.

However, in a conductive transparent oxide made of ZnO as a main component, an oxygen defect is likely to be introduced, and a large number of carrier electrons are generated, whereby it is difficult to reduce an electric conductivity. As a result, even when no gate voltage is applied, a large current is caused to flow between a source terminal and a drain terminal, whereby the normally-off operation of TFT cannot be achieved. In addition, it is also difficult to increase an on-off ratio of the transistor.

Generally, in a display device for displaying an image, a semiconductor layer, a pixel electrode layer and a storage capacitor electrode layer are formed of different materials from one another, and therefore it is necessary to separately form the semiconductor layer, the pixel electrode layer and the storage capacitor electrode layer.

In the case of forming the semiconductor layer separately from the pixel electrode layer and the storage capacitor electrode layer, steps and structure thereof becomes complicated. In addition, because of use of an optically opaque material such as a gate wiring or a metal wiring formed on an upper layer, there is a possibility that an aperture ratio is reduced, a transmittance of backlight is deteriorated, and display luminance is reduced.

### SUMMARY OF THE INVENTION

An object of the present invention is to provide a light control device including: a thin film transistor; and a light control element including an electrode electrically connected to the thin film transistor, in which a semiconductor region of the thin film transistor and the electrode are composed of the same semiconductor layer, and the semiconductor layer is an amorphous layer of the oxide containing at least one of In, Ga and Zn.

In the present invention, the same semiconductor layer indicates a semiconductor layer formed of the same main component, which includes both cases of the same semiconductor layer (integrally formed) and a semiconductor layer separately provided.

The electrode may include a storage capacitor electrode for storage of electric charges. Further, the semiconductor region of the thin film transistor may be electrically connected to a wiring at a portion different from a connection portion of the electrode of the semiconductor region of the thin film transistor, and the wiring may include the semiconductor layer.

Further, another object of the present invention is to provide a display employing the above-described light control device according to the present invention.

The light control element is an element for controlling light with a current or a voltage, which includes a light-emitting element for controlling light emission, a light-transmittance control element for controlling transmittance of light, or a light-reflectance control element for controlling reflectance of light.

Further features of the present invention will become apparent from the following description of exemplary embodiments with reference to the attached drawings.

### BRIEF DESCRIPTION OF THE DRAWINGS

FIG. 1 is a sectional view illustrating a mode of a light control device according to an embodiment of the present invention.

FIG. 2 is a sectional view illustrating another mode of the light control device according to the embodiment of the present invention.

FIGS. 3A, 3B, 3C and 3D are sectional views each illustrating the manufacturing steps of the light control device according to the embodiment of the present invention.

FIG. 4 is a characteristic diagram illustrating a conductivity of an amorphous film composed of the oxide containing at least one of In, Ga and Zn when a hydrogen ion is implanted into the amorphous film composed of the oxide containing at least one of In, Ga and Zn.

FIG. 5 is a characteristic diagram illustrating a relationship between an oxygen partial pressure and an electron carrier concentration.

FIG. 6 is a characteristic diagram illustrating a relationship between the electron carrier concentration and an electron mobility.

FIG. 7 is a characteristic diagram illustrating a relationship between the oxygen partial pressure and an electrical conductivity.

FIG. 8 is a diagram illustrating a structure of an image display in which pixels including an organic EL device and a thin film transistor are arranged two-dimensionally.

FIG. 9 is a sectional view illustrating another mode of the light control device according to the embodiment of the present invention.

FIG. 10 is a sectional view illustrating a mode of a light control device in which a structure of a storage capacitor is additionally provided according to the embodiment of the present invention.

FIG. 11 is a sectional view illustrating another mode of the light control device in which the structure of the storage capacitor is additionally provided according to the embodiment of the present invention.

FIG. 12 is a sectional view illustrating a mode of a light control device in which the structure of the storage capacitor is additionally provided and which is applied to a wiring according to the embodiment of the present invention.

FIG. 13 is a perspective view illustrating another mode of the light control device in which the structure of the storage capacitor is additionally provided and which is applied to the wiring according to the embodiment of the present invention.

### DESCRIPTION OF THE EMBODIMENTS

(1) First, an oxide film having an electron carrier concentration of less than 10¹⁸/cm³ which has been successfully formed by the inventors of the present invention will be described in detail. (After that, a detailed structure of the present invention itself will be described as item (2).)

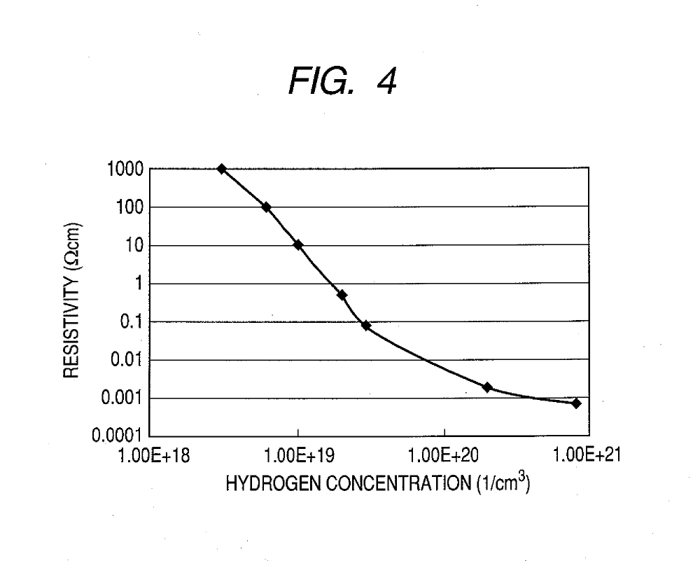

As an exploratory experiment, a hydrogen ion was implanted into an amorphous film of the oxide containing at least one of In, Ga, and Zn to obtain a conductivity thereof at the time. FIG. 4 illustrates an experimental result thereof. It was found that when the hydrogen ion concentration became 10¹⁹ (i.e., 1.00E+19)/cm³ or more, the conductivity was lowered sufficiently.

Specifically, the above-described oxide film is an amorphous oxide film which contains at least one of In, Ga, and Zn has a composition in a crystalline state represented by InGaO₃(ZnO)ₘ (where m represents a natural number of less than 6), and has an electron carrier concentration of less than 10¹⁸/cm³.

Alternatively, the oxide film is an amorphous oxide film which contains at least one of In, Ga, and Zn has a composition in a crystalline state represented by InGaO₃(Zn₁₋ₓMgₓO)ₘ (where m represents a natural number of less than 6 and 0<x<1), and has an electron carrier concentration of less than 10¹⁸/cm³.

The films can be further designed to have an electron mobility of 1 cm²/(V·sec) or more.

It has been found that the use of the film for a channel layer enables production of a flexible TFT which has the transistor characteristics such that a gate current at the time of turning a transistor off is less than 0.1 μA, that is, normally off, and an on-off ratio is 10³ or more, and which is transparent to visible light.

The electron mobility of the above-described film increases with increasing number of conduction electrons. A glass substrate, a plastic substrate made of a resin, a plastic film, or the like can be used as a substrate on which a transparent film is to be formed.

When the amorphous oxide film is used for a channel layer, SiOx, SiNx, Al₂O₃, Y₂O₃, or HfO₂, or a mixed crystal compound containing at least two kinds of these compounds can be used for a gate insulating film to form the transistor.

The amorphous oxide can be formed into a film in an atmosphere containing an oxygen gas without intentionally adding any impurity ion for increasing an electrical resistance.

The inventors of the present invention have found that the semi-insulating oxide amorphous thin film has a specific property in which the electron mobility of the film increases with the increasing number of conduction electrons. Further, the inventors have found that a TFT produced by means of the film is further improved in transistor characteristics such as an on/off ratio, a saturation current in a pinch-off state, and a switching speed.

In a case where the amorphous oxide thin film for a channel layer of a film transistor, when an electron mobility is 1 cm²/(V·sec) or more, or desirably 5 cm²/(V·sec) or more, and the electron carrier concentration is less than 10¹⁸/cm³, or desirably less than 10¹⁶/cm³, a current flowing between drain and source terminals at the time of off-state (when no gate voltage is applied) can be set to be less than 10 μA, or desirably less than 0.1 μA. The use of the above-described film provides a saturation current after pinch-off of 10 μA or more and an on/off ratio of 10³ or more when the electron mobility is 1 cm²/(V·sec) or more, or desirably 5 cm²/(V·sec) or more.

In a TFT, a high voltage is applied to a gate terminal in a pinch-off state, and electrons are present in a channel at a high density. Therefore, according to the present invention, a saturation current value can be increased by an amount corresponding to an increase in electron mobility. As a result, improvements of almost all of the transistor characteristics including an increase in on/off ratio, an increase in saturation current, and an increase in switching speed can be realized. In usual compounds, when the number of electrons increases, an electron mobility reduces owing to a collision between electrons.

Examples of a structure that can be used for the TFT include: a staggered (top gate) structure in which a gate insulating film and a gate terminal are formed in mentioned order on a semiconductor channel layer; and an inversed staggered (bottom gate) structure in which a gate insulating film and a semiconductor channel layer are formed in mentioned order on a gate terminal.

On the other hand, when the amorphous oxide thin film is used for the transparent electrode portion, a resistivity is desirably in a range from about 100 to 10⁻³ Ωcm.

### Film Composition

The amorphous state of an amorphous oxide thin film having a composition in a crystalline state which is represented by InGaO₃(ZnO)ₘ (where m represents a natural number of less than 6) is stably maintained up to a high temperature of 800° C. or higher when the value for m is less than 6. However, as the value of m increases, that is, as a ratio of ZnO to InGaO₃ increases to cause the composition to be close to a ZnO composition, the thin film is apt to crystallize.

Therefore, a value for m of less than 6 is desirable for a channel layer of an amorphous TFT.

A vapor phase film formation method involving the use of a polycrystalline sintered material having an InGaO₃(ZnO)m composition as a target is a desirable method for forming the amorphous oxide film. Of the vapor phase film formation methods, a sputtering method and a pulse laser deposition method are suitable. Further, the sputtering method is most suitable from the viewpoint of mass productivity.

However, when the amorphous film is produced under normal conditions, an oxygen defect mainly occurs, so that it was not able to obtain a film having an electron carrier concentration of less than 10¹⁸/cm³, that is, an electric conductivity of 10 S/cm or less. The use of a film not satisfying such characteristics makes it impossible to constitute a normally-off transistor. The present inventors formed an amorphous oxide film containing at least one of In, Ga, and Zn and having a composition in a crystalline state which is represented by InGanO3(ZnO)m (where n and m represents a whole number of less than 6), and which was produced by a pulse laser deposition method under an atmosphere having a high oxygen partial pressure of 4.5 Pa or more. As a result, it was able to reduce the electron carrier concentration to less than 10¹⁸/cm³. In this case, the substrate had a temperature maintained at a temperature nearly equal to a room temperature unless intentionally heated. The substrate temperature is desirably kept at a temperature lower than 100° C. in order that a plastic film made of a resin and having a low heat resistance can be used as a substrate.

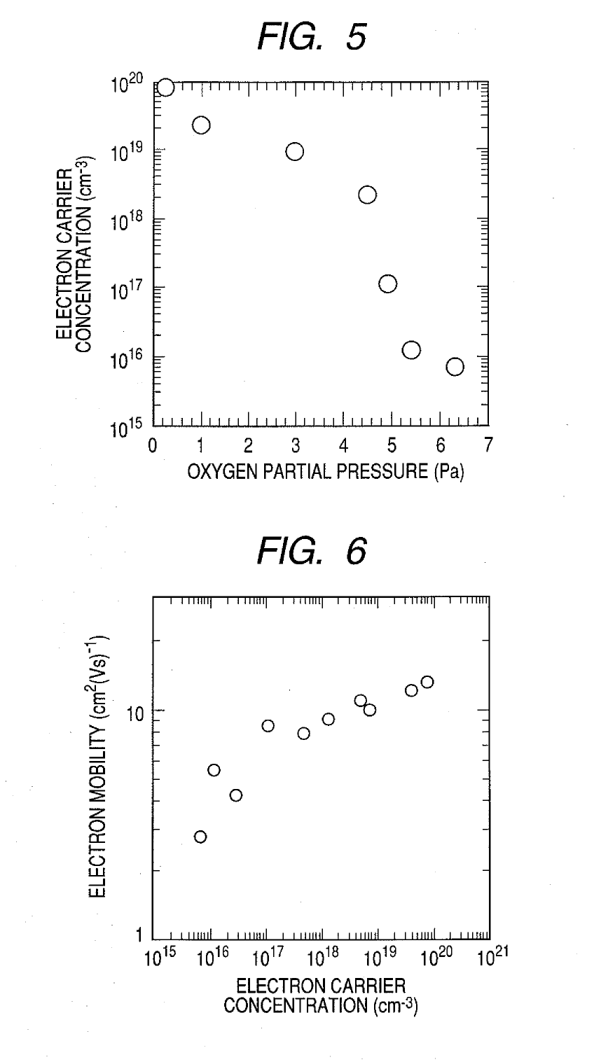

Further increase of the oxygen partial pressure makes it possible to reduce the number of electron carriers. For example, as shown in FIG. 5, an InGaO₃(ZnO)₄ film formed at a substrate temperature of 25° C. and an oxygen partial pressure of 6 Pa had the number of electron carriers further reduced to about 10¹⁶/cm³ (electric conductivity of about 10⁻⁴ S/cm). As shown in FIG. 6, the obtained film had a electron mobility of 1 cm²/(V·sec). However, in the pulse laser deposition method, when the oxygen partial pressure is set to be 6.5 Pa or more, the surface of the deposited film becomes uneven, and therefore the obtained film cannot be used as the channel layer of the TFT.

Specifically, under an atmosphere of an oxygen partial pressure of 4.5 Pa or more, desirably 5 Pa or more and less than 6.5 Pa, the use of an amorphous oxide film which is composed of at least one of In, Ga, and Zn produced by the pulse laser deposition method, and has a composition in a crystalline state represented by InGaO₃(ZnO)ₘ (where m represents a natural number of less than 6) makes it impossible to constitute a normally-off transistor.

Specifically, the oxygen partial pressure in a case of producing a film by the pulse laser deposition method is 4.5 Pa or more and less than 6.5 Pa, more desirably 5 Pa or more and less than 6.5 Pa.

The electron mobility of the film was 1 cm²/V sec or more, and the on/off ratio was increased to 10³ or more.

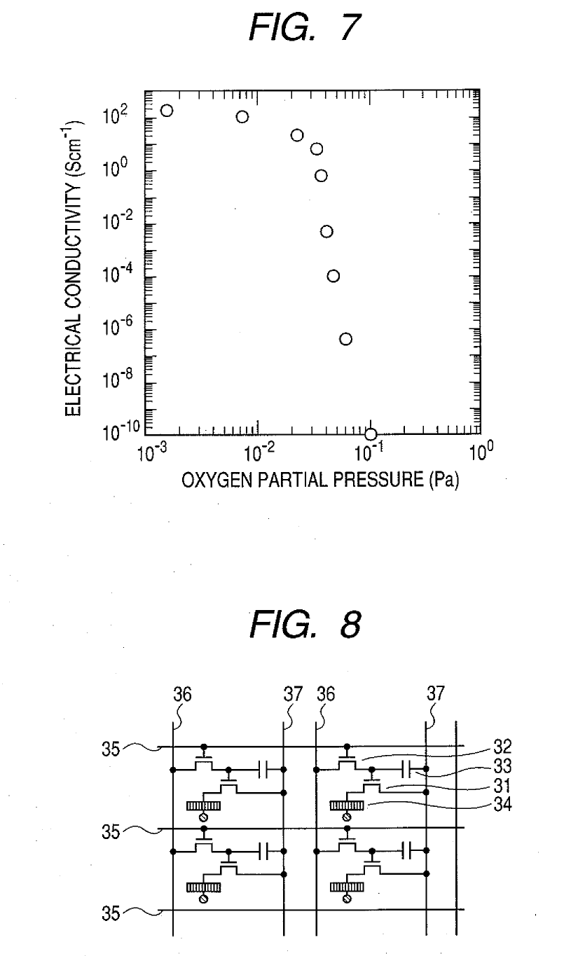

Further, an amorphous oxide film containing at least one of In, Ga, and Zn and having a composition in a crystalline state represented by InGaO₃(ZnO)ₘ (where m represents a natural number of less than 6) is formed under an atmosphere of an oxygen partial pressure of 3×10⁻² Pa or more by the sputtering method using also an argon gas. Thus, as shown in FIG. 7, the electric conductivity was able to be reduced to less than 10 S/cm. In this case, the temperature of the substrate was maintained at a temperature nearly equal to a room temperature without intentionally heating. The substrate temperature is desirably kept at a temperature lower than 100° C. in order to enable a plastic film made of a resin and having a low heat resistance to be used as a substrate. Further increase of the oxygen partial pressure could make it possible to reduce the number of electron carriers. For example, as shown in FIG. 7, an InGaO₃(ZnO)₄ film formed at a substrate temperature of 25° C. and an oxygen partial pressure of 10⁻¹ Pa could have an electric conductivity further reduced to about 10⁻¹⁰ S/cm. In addition, an InGaO₃(ZnO)₄ film formed at an oxygen partial pressure of 10⁻¹ Pa or more had so high an electrical resistance that the electric conductivity thereof could not be measured.

A film having an electrical resistance of 10⁻² S/cm or more had an electron mobility of 1 cm²/(V·sec) or more. A film having an electrical resistance of 10⁻² S/cm or less had so high an electrical resistance that the electron mobility could not be measured, but it was estimated to be about 1 cm²/(V·sec) as a result of extrapolation from the relationship between the measured electrical resistance and the electron mobility.

Specifically, an amorphous oxide film containing at least one of In, Ga, and Zn and having a composition in a crystalline state represented by InGaO₃(ZnO)ₘ (where m represents a natural number of less than 6) which was by the sputtering method was used to able to be produced a normally-off transistor having an on/off ratio of 10³ or more. The sputtering deposition was performed under an atmosphere of an argon gas with an oxygen partial pressure of 3×10⁻¹ Pa or more, desirably 5×10⁻¹ Pa or more.

In the film produced by the pulse laser deposition method and the sputtering method, the electron mobility of the film increases with increasing the number of conduction electrons.

Similarly, the use of a polycrystalline InGaO₃(Zn₁₋ₓMgₓO)ₘ (where m represents a natural number of less than 6 and 0<x<1) as a target was able to obtain a high-resistance amorphous InGaO₃(Zn₁₋ₓMgₓO)ₘ film even at an oxygen partial pressure of less than 1 Pa. For example, when a target obtained by substituting 80 atomic % of Mg for Zn is used, the electron carrier concentration of a film obtained by means of the pulse laser deposition method in an atmosphere having an oxygen partial pressure of 0.8 Pa can be less than 10¹⁶/cm³ (the electrical resistance is about 10⁻² S/cm). The electron mobility of this film reduces as compared to the film added with no Mg, but the degree of the reduction is small. The electron mobility at a room temperature is about 5 cm²/(V·sec), which is about one order of magnitude larger than that of an amorphous silicon. Upon film formation under the same conditions, both the electric conductivity and the electron mobility reduce with increasing the Mg content. Therefore, the Mg content is desirably 20% or more and less than 85% (that is, 0.2<x<0.85).

As described above, controlling an oxygen partial pressure can reduce oxygen defects, thereby making it possible to reduce an electron carrier concentration without adding a specific impurity ion. In addition, in an amorphous state, unlike a polycrystalline state, substantially no grain boundary is present, so that an amorphous thin film having a high electron mobility can be obtained. Further, the number of conduction electrons can be reduced without adding a specific impurity, whereby it is possible to keep the electron mobility at a high level without causing scattering by the impurity.

In the thin film transistor using the amorphous film, SiOx, SiNx, A1₂O₃, Y₂O₃, HfO₂ or a mixed crystal compound containing at least two kinds of these compounds can be used for a gate insulating film. When a defect is present in an interface between the gate insulating thin film and the channel layer thin film, an electron mobility reduces and hysteresis occurs in transistor characteristics. In addition, a leakage current varies to a large extent depending on the kind of the gate insulating film. For this reason, a gate insulating film suitable for a channel layer must be selected. The use of an SiOx, SiNx, or A1₂O₃ film can reduce a leakage current. In addition, the use of a Y₂O₃ film can reduce hysteresis. Further, the use of an HfO₂ film having a high dielectric constant can increase the electron mobility. Further, the use of mixed crystal of those films can result in the formation of a TFT having a small leak current, small hysteresis, and a large electron mobility. Further, each of a gate insulating film forming process and a channel layer forming process can be performed at a room temperature, whereby each of a staggered structure and an inversed staggered structure can be formed as a TFT structure.

The TFT thus formed is a three-terminal device including a gate terminal, a source terminal, and a drain terminal. Also, the TFT is an active device using a semiconductor thin film formed on an insulating substrate such as a ceramic, glass, or plastic as a channel layer in which an electron or a hole moves, and having the function of controlling a current flowing in the channel layer to thereby control a current between the source terminal and the drain terminal by applying a voltage to the gate terminal.

To achieve a desired electron carrier concentration by controlling an oxygen defective amount is important in this embodiment.

In the above description, the amount oxygen (oxygen defective amount) of an amorphous oxide film is controlled by performing film formation under an atmosphere containing a predetermined concentration of oxygen. It is also desirable to control (reduce or increase) the oxygen defective amount by subjecting the oxide film after the film formation to a post treatment under an atmosphere containing oxygen.

To effectively control the oxygen defective amount, the temperature of the atmosphere containing oxygen is in the range of desirably 0° C. or more and 300° C. or less, preferably 25° C. or more and 250° C. or less, or more preferably 100° C. or more and 200° C. or less.

The film formation may be performed under the atmosphere containing oxygen, and the post treatment after the film formation may be performed under the atmosphere containing oxygen. In addition, the oxygen partial pressure may be controlled, not during film formation but in a post treatment after the film formation, under the atmosphere containing oxygen as long as a desired electron carrier concentration (less than 10¹⁸/cm³) can be obtained.

The lower limit for the electron carrier concentration according to this embodiment, which varies depending on the kind of an element, circuit, or device for which an oxide film to be obtained is used, is, for example, 10¹⁴/cm³ or more.

Further, the pixel electrode portion is required to have a low resistance as compared to the semiconductor portion. As described with reference to FIG. 4, increase of the hydrogen concentration can reduce the resistivity. Deuterium may be introduced in place of hydrogen. In the pixel electrode portion, a concentration of hydrogen or deuterium contained in an amorphous oxide film containing at least one of In, Ga, and Zn is desirably 5×10¹⁹ or more. As a method of increasing the concentration of hydrogen or deuterium contained in the amorphous film, an ion implantation method, hydrogen plasma, or the like may be employed. In performing those treatments, a pattern in which the pixel electrode portion has an opening is formed with a resist, to thereby prevent the hydrogen from entering the semiconductor portion. The upper limit of the concentration of hydrogen or deuterium is not particularly defined, but is determined according to the constraint on a manufacturing process such as a manufacturing time.

Similarly, in a one-side electrode of the storage capacitor electrode, the concentration of hydrogen or deuterium contained in the amorphous oxide film containing at least one of In, Ga, and Zn is desirably 5×10¹⁹ or more.

Further, in a case where the low resistance film, which is obtained by high concentration doping of hydrogen or deuterium into an amorphous oxide film containing containing at least one of In, Ga, and Zn, is assumed to be applied to wirings, the concentration of hydrogen or deuterium is desirably 5×10¹⁹ or more. The present inventors have confirmed that the amorphous oxide film containing at least one of In, Ga, and Zn O to which hydrogen is doped at a high concentration has a resistivity of about 10⁻² Ω·cm, which is about one order of magnitude larger than a resistivity of about 10⁻³ Ω·cm of a wiring material of AlSi or the like used for the semiconductor process.

The material system has a high optical transmission property, so that there is no restriction in terms of optical shielding even when it is applied to wirings, which allows a degree of freedom of design. Therefore, an influence of the resistivity which is higher than that of a conventional metal wiring can be reduced by increasing a wiring width in design.

(2) Next, a structure according to this embodiment of the present invention will be described in detail.

The present invention relates to a light control device including a field effect TFT having the above-described amorphous film as an active layer, and a light control element using the field effect TFT, and to an image display in which the light control devices are arranged. The display is also used for an apparatus including the display, building structures, and structures of a movable body.

Specifically, according to this embodiment, there is provided, first, a light control device having an electrode connected to a drain that is an output terminal of the field effect TFT. The light control element is, for example, a light-emitting element such as an electroluminescent element, a light transmittance control element of a liquid crystal cell or an electrophoretic particle cell, or a light reflectance control element. An example of the device structure will be described below in detail with reference to a sectional view of the light control device.

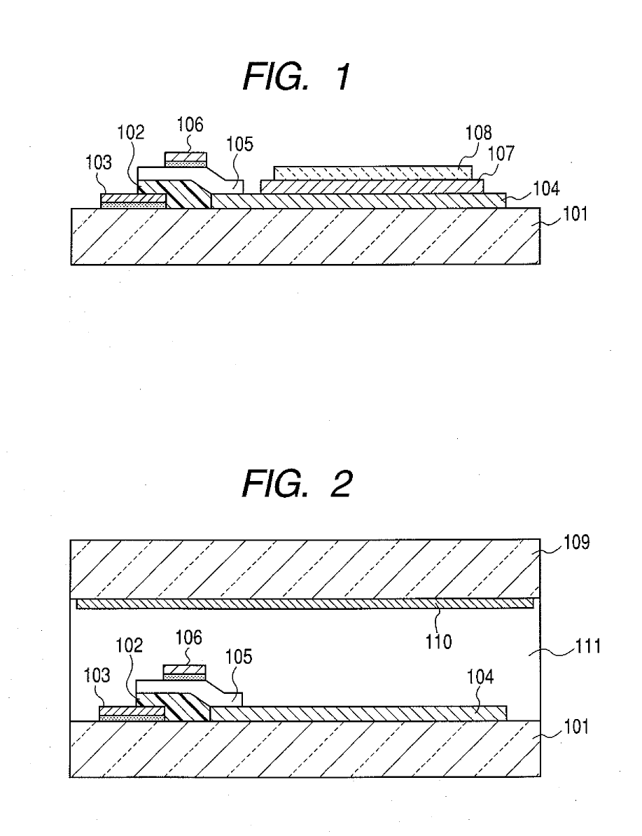

As shown in FIG. 1, the TFT includes an amorphous oxide semiconductor portion (semiconductor region of the thin film transistor) 102, a source electrode 103, a drain electrode portion (pixel electrode) 104, a gate insulating film 105, and a gate electrode 106. The amorphous oxide semiconductor portion 102 and the drain electrode (pixel electrode) 104 are formed in the same semiconductor layer. The drain electrode 104 of the TFT also functions as the pixel electrode. In the light control element, the pixel electrode portion 104 is in contact with a light-emitting layer 107 and the light-emitting layer 107 is in contact with an upper electrode 108. With the structure, a current injected into the light-emitting layer 107 can be controlled with a current value flowing from the source electrode 103 to the drain electrode/pixel electrode 104 through a channel formed in the amorphous oxide semiconductor portion 102. Therefore, the current injected into the light-emitting layer 107 can be controlled with a voltage of the gate electrode 106 of the TFT. In this case, the light-emitting layer 107 may be an inorganic or organic electroluminescence device.

Alternatively, as shown in FIG. 2, the light control element can employ a structure of a light transmittance control element or a light reflectance control element including a liquid crystal cell or an electrophoretic particle cell by sandwiching a liquid crystal layer or an electrophoretic particle layer between the pixel electrode 104 and a pixel electrode 110 formed on an opposing substrate 109 which is another substrate. With the structure, it is possible to control the voltage applied to the light transmittance control element or the light reflectance control element with the current value flowing from the source electrode 103 to the drain electrode 104 through the channel formed in the amorphous oxide semiconductor 102. As a result, the voltage can be controlled with the voltage of the gate electrode 106 of the TFT.

A representative structure for each of the TFT's in the above-mentioned two examples is a top gate and coplanar structure. However, this embodiment is not necessarily limited to the structure. Any other structure such as a staggered structure can also be adopted as long as a drain electrode as an output terminal of a TFT and a light-emitting element are connected so as to be topologically identical to each other.

Further, only one TFT to be connected to a light-emitting element, a light transmittance control element, or a light reflectance control element is illustrated in each of the above-mentioned two examples. However, this embodiment is not necessarily limited to the structure. The TFT illustrated in the figure may be connected to another TFT according to the present invention as long as the TFT illustrated in the figure corresponds to the final stage of a circuit constituted by the TFT's.

When a pair of electrodes for driving a light-emitting element, a light transmittance control element, or a light reflectance control element is arranged in parallel with a substrate, an electrode of one of the light-emitting element and the light reflectance control element must be transparent with respect to a luminous wavelength or the wavelength of reflected light. Alternatively, both electrodes of a light transmittance control element must be transparent with respect to transmitted light.

Further, all constituents of the TFT according to this embodiment may be transparent. In this case, a transparent light control element can be obtained. In addition, the light control element can be arranged on a substrate having low heat resistance such as a light weight, flexible, and transparent plastic substrate made of a resin.

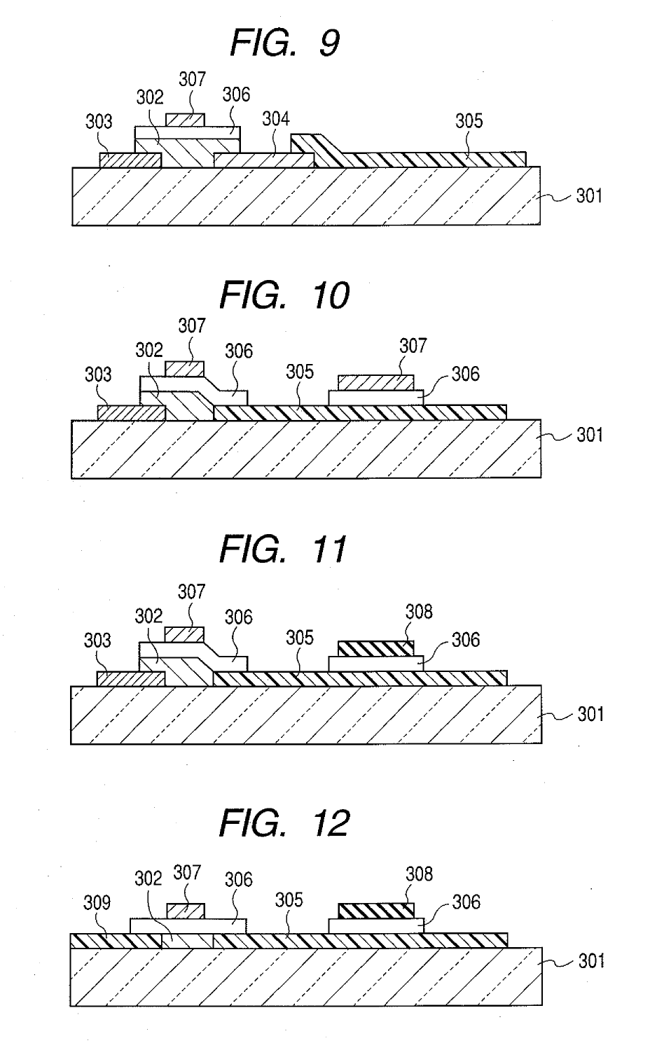

In the embodiment as described above, the light control element has a structure in which the semiconductor region of the thin film transistor and the pixel electrode of the light control element are in contact with each other, but the semiconductor region and the pixel electrode may be formed separately. FIG. 9 is a sectional diagram illustrating an example of the structure. As shown in FIG. 9, the light control element includes a substrate 301, a semiconductor layer 302 of a thin film transistor, a source electrode 303, a drain electrode 304, a pixel electrode 305, a gate insulating film 306, and a gate electrode 307. The semiconductor layer 302 and the pixel electrode 305 are formed of the same semiconductor layer, and hydrogen or deuterium is introduced in the pixel electrode portion to obtain a low resistance. The semiconductor layer (semiconductor region) 302 is electrically connected to the pixel electrode 305 through the drain electrode 304.

In the above-mentioned embodiment, the storage capacitor electrode is not referred to, but as illustrated in FIG. 10, for example, it is also possible to use a laminated structure of the low resistance layer 305 in which hydrogen or deuterium is introduced, the gate insulating film 306, and the gate electrode 307 as the storage capacitor electrode for storage of electric charges. An end portion of the low resistance layer 305 is in contact with and electrically connected to the semiconductor region of the thin film transistor, and functions as a drain electrode. The low resistance layer 305 also functions as an pixel electrode.

Further, as shown in FIG. 11, instead of the gate electrode 307 of the storage capacitor electrode, for example, a transparent conductive film 308 formed of a material such as ITO can be used to form the storage capacitor electrode. In this case, in addition to simplification of processes, an optical numerical aperture can be improved.

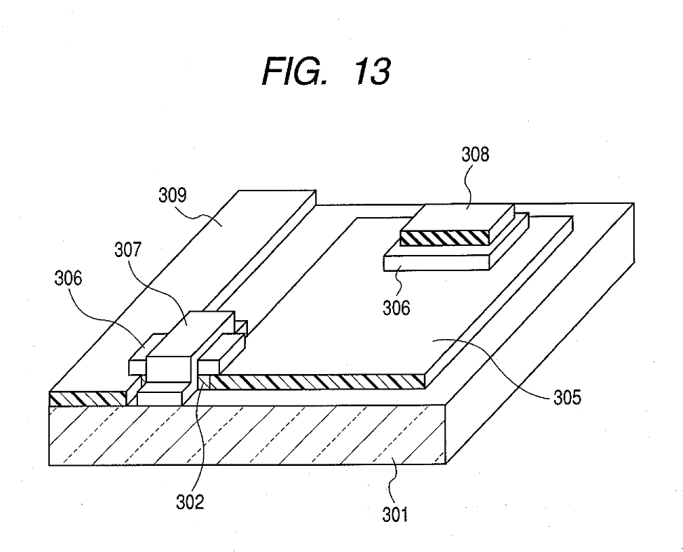

As shown in FIGS. 12 and 13, a data line wiring (source wiring) 309 can be formed in the same process of forming the low resistance layer 305. The data line wiring 309 and the source electrode may be provided separately, but, in this case, a part of the data line wiring 309 is in contact with the semiconductor region of the thin film transistor and functions as a source electrode. The data line wiring 309 is in contact with and electrically connected to the semiconductor layer 302 on an opposite side of the connection side of the pixel electrode 305 of the semiconductor layer 302. The data line wiring 309 is not necessarily provided on the opposite side thereof by sandwiching the semiconductor layer 302. In other words, it is sufficient that the data line wiring 309 is in contact with and electrically connected to a part (region) of the semiconductor layer 302 which is different from the connection portion of the pixel electrode 305 of the semiconductor layer 302. In the case where the data line wiring 309 and the source electrode are provided separately, the data line wiring 309 is not connected to the semiconductor layer 302 directly, so it is possible to arbitrarily arrange the data line wiring 309 with respect to the semiconductor layer 302.

According to a second embodiment, there is provided a display in which the above-mentioned light control elements are arranged two-dimensionally together with the TFT's wired in an active matrix manner. For example, an active matrix circuit in which the gate electrode 106 of one TFT for driving a light control element is connected to a gate line of an active matrix and the source electrode of the TFT is wired to a target to which a signal is transmitted is constituted. With the structure, a display using each light control element as a pixel can be provided. Further, when a plurality of light control elements adjacent to each other and different from each other in light emission wavelength, transmitted light wavelength, or reflected light wavelength constitute one pixel, a color display can be provided.

The display according to this embodiment can be applied to various electric apparatus and constructions as described below.

For example, as a first application, there is a broadcasting dynamic display apparatus such as a television receiving set including the above-mentioned display. In particular, the display according to this embodiment provides a portable broadcasting dynamic image display apparatus with a light weight, flexibility, and safety with respect to breakage.

As a second application, there is a digital information processing apparatus such as a computer including the above-mentioned display. The display according to this embodiment has a light weight and is flexible, so the display provides a desktop computer display with the degree of freedom of installation and with portability. Further, the display provides a portable digital information processing apparatus such as a laptop computer or a personal digital support equipment with a light weight, flexibility, and safety with respect to breakage.

As a third application, there is provided a portable information equipment such as a cellular phone, a portable music reproducer, a portable dynamic image reproducer, or a head mount display including the above-mentioned display. The display according to this embodiment provides the portable information equipment with a light weight, flexibility, and safety with respect to breakage. In particular, when the display of the present invention which is made transparent is used for a head mount display, a see-through device can be provided.

As a fourth application, there is provided an image pickup device such as a still camera or a movie camera including the above-mentioned display. The above-mentioned display can be provided for a viewfinder of the image pickup device, for acknowledgement of picked up image, or for display of image pickup formation. The display according to this embodiment provides any one of those image pickup devices with a light weight, flexibility, and safety with respect to breakage.

As a fifth application, there is provided a building structure such as a window, a door, a ceiling, a floor, an inner wall, an outer wall, or a partition including the above-mentioned display. Since the display according to this embodiment has a light weight and flexibility, and can be made transparent, the display can be easily attached to any one of those building structures. In addition, the display does not impair the external appearance of the building structure when no image is displayed.

As a sixth application, there is provided a structure such as a window, a door, a ceiling, a floor, an inner wall, an outer wall, or a partition for a movable body such as a vehicle, an airplane, or a ship including the above-mentioned display. Since the display according to this embodiment has a light weight and flexibility, and can be made transparent, the display can be easily attached to any one of those building structures. In addition, the display does not impair the external appearance of the building structure when no image is displayed. In particular, when the display which is made transparent is used for a transparent window for monitoring and observing the surroundings of a movable body, the display can display an information image only if needed and does not inhibit the monitoring and observation of the surroundings if such an image is not needed.

As a seventh application, there is provided an advertising device such as an advertising unit in a vehicle of a public transportation, or a signboard or advertising tower in a city including the above-mentioned display. The display according to this embodiment can not only always replace an invariable medium such as a printed material that has been mainly used for any adverting device heretofore but also display a dynamic image.

Hereinafter, a display in which pixels including EL devices (herein, organic EL devices) and thin film transistors are arranged two-dimensionally will be described with reference to FIG. 8.

As shown in FIG. 8, the display includes a transistor 31 for driving an organic EL layer 34, and a transistor 32 for selecting a pixel. A capacitor 33 holds a state in which a pixel is selected, stores electric charges between a common electrode line 37 and a source portion of the transistor 32, and holds a signal of a gate of the transistor 31. Selection of a pixel is determined with a scanning electrode line 35 and a signal electrode line 36. As shown in FIG. 1, the pixel electrode of the organic EL layer 34 also functions as a drain electrode of the transistor 31, and the semiconductor layer of the transistor 31 is in contact with the pixel electrode.

More specifically, an image signal is sent from a driver circuit (not shown) through the scanning electrode line 35 and is applied to the gate electrode with a pulse signal. At the same time, the image signal is sent from another drive circuit (not shown) through the signal electrode line 36 and is applied to the transistor 32 with a pulse signal, to thereby select a pixel. In this case, the transistor 32 is turned on and electric charges are stored in the capacitor 33 provided between the signal electrode line 36 and the source of the transistor 32. As a result, a gate voltage of the transistor 31 is maintained at a desired voltage, and the transistor 31 is turned on. The state is maintained until the transistor receives the subsequent signal. In the state in which the transistor 31 is on, the organic EL layer 34 is continuously supplied with a voltage and a current, and emission of light is maintained.

In the example of FIG. 8, one pixel contains two transistors and one capacitor, but more transistors or the like may be incorporated therein for improvement of the performance. It is essential that an In—Ga—Zn—O-based TFT which can be formed at low temperature and is transparent is used for a transistor portion, thereby making it possible to obtain an effective EL device.

Next, examples of the present invention will be described with reference to the drawings.

### EXAMPLE 1

First, a method of forming a thin film transistor and a pixel electrode which can be applied to this embodiment will be described.

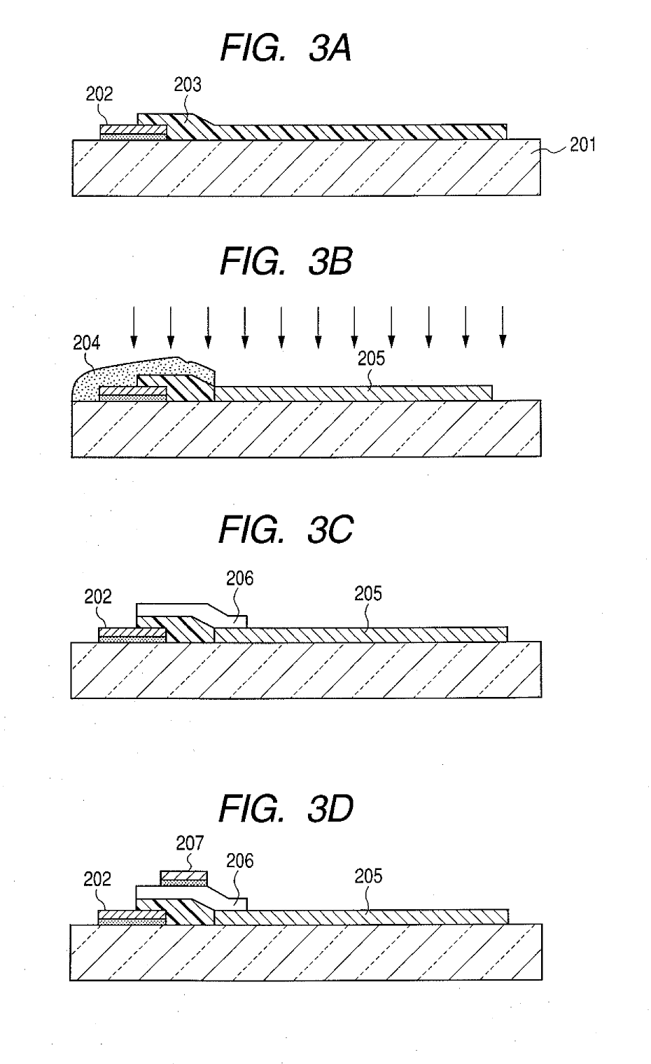

With reference to FIGS. 3A to 3D, the method of producing a thin film transistor and a light control element according to this embodiment will be described.

First, as shown in FIG. 3A, Ti and Au were deposited in thicknesses of 10 nm and 40 nm, respectively, on an alkali-free glass substrate which was a transparent substrate by a sputtering method, and patterning was performed by photolithography, to thereby form a source electrode 202. By the sputtering method using a polycrystal sintered body having InGaO₃(ZnO)₄ composition as a target, an In—Ga—Zn—O-based amorphous oxide semiconductor film 203 having a film thickness of 50 nm was deposited on the alkali-free glass substrate and was subjected to patterning. An oxygen partial pressure in a chamber was 5×10⁻² Pa and a substrate temperature was 120° C. Then, as shown in FIG. 3B, portions other than the pixel portion was protected with a photo resist 204, and hydrogen ion was implanted thereinto with an amount of 2×10²⁰/cm³ by ion plantation.

The pixel electrode portion 205 became a low resistant film having a resistivity of 0.1 Ωcm.

As shown in FIG. 3C, a Y₂O₃ film was further deposited in a thickness of 140 nm by the sputtering method and patterning was performed to obtain a gate insulating film 206. Finally, as shown in FIG. 3D, Ti and Au were deposited in thicknesses of 10 nm and 40 nm, respectively, and patterning was performed, to thereby form a gate electrode 207. The TFT had a length of 10 μm and a width of 20 μm. Thus, a field effect n-channel TFT was produced.

The TFT exhibited characteristics of a field effect mobility of 5 cm²V⁻¹s⁻¹, a threshold voltage of 1 V, and an on/off ratio of a value having about three orders or more.

A method of partially improving the conductivity of the In—Ga—Zn—O-based amorphous oxide semiconductor film is as follows. After a semiconductor element portion is masked, irradiation with energy such as an X-ray or an electron beam, and an oxygen defect is caused in the film, thereby making it possible to cause a carrier. An X-ray desirably has a component having a wavelength of 1.5 nm or less as a main component. An electron beam desirably has a component having a wavelength of 1.5 nm or less as a main component.

In the TFT, a shorter side of an island of a semiconductor layer which is caused to have a low resistance and serves as the drain electrode and the pixel electrode is extended up to 100 μm. The extended 90-μm portion is left, and the TFT is coated with an insulating layer after wiring to the source electrode and the gate electrode is secured. A polyimide film is applied thereonto and the obtained substrate is subjected to a rubbing process. Meanwhile, a plastic substrate having an ITO film and a polyimide film formed thereon and subjected to the rubbing step is separately prepared. The substrate on which the TFT and the pixel electrode have been formed are arranged opposite to the separately prepared substrate with a gap of 5 μm therebetween. A nematic liquid crystal is injected into the gap. Further, a pair of polarizing plates is arranged on both sides of the arranged substrates. In this case, when a voltage is applied to the source electrode of the TFT and a voltage to be applied to the gate electrode is changed, the light transmittance of only a pixel electrode region having a low resistance changes. The transmittance can be continuously changed by a voltage applied between the source and drain electrodes at a gate voltage with which the TFT is in on state. Thus, the light control device including a liquid crystal cell which functions as the light transmittance control element is produced as shown in FIG. 2.

In this example, a white plastic substrate (which becomes a flexible resin substrate) is used as a substrate on which a TFT is to be formed, and the source electrode of the TFT is replaced with gold. Then, a polyimide film and a polarizing plate are not used, and a gap between white and transparent plastic substrates is filled with a capsule obtained by coating a particle and a fluid with an insulating coat. In this case, a voltage applied between the pixel electrode which also functions as the extended drain electrode and the upper ITO film is controlled by the TFT. As a result, it is possible to produce the light control element using the light reflectance control element, in which the vertical movement of the particle in the capsule enables the reflectance of the pixel electrode region which also functions as the extended drain electrode seen from the side of the transparent substrate to be controlled.

Further, in this example, a plurality of TFT's are formed so as to be adjacent to each other to constitute, for example, a current control circuit generally composed of four transistors and one capacitor, and the TFT shown in FIG. 1 may be used for one transistor on the final stage among the transistors to drive a light-emitting element. For example, the above-mentioned TFT using a low resistance In—Ga—Zn—O film as an electrode is used, and an organic electroluminescent element including a charge-injecting layer and a light-emitting layer is formed on a region of the pixel electrode, thereby making it possible to produce the light control element using the light-emitting element.

### Example 2

The example using other materials is shown using the same figure. As shown in FIG. 3A, Ti and Au were deposited in thicknesses of 10 nm and 40 nm, respectively, on an alkali-free glass substrate which was a transparent substrate by a sputtering method, and patterning was performed by photolithography, to thereby form a source electrode 202. By the sputtering method using a polycrystal sintered body having In₂O₃/ZnO (90:10 wt %) composition as a target, an In—Zn—O-based amorphous oxide semiconductor film 203 having a film thickness of 50 nm was deposited on the alkali-free glass substrate and was subjected to patterning. An oxygen partial pressure in a chamber was 5×10⁻² Pa and a substrate temperature was 120° C. Then, as shown in FIG. 3B, portions other than the pixel portion was protected with a photo resist 204, and hydrogen ion was implanted thereinto with an amount of 3×10²⁰/cm³ by ion plantation.

The pixel electrode portion 205 became a low resistant film having a resistivity of 0.15 Ωcm

As shown in FIG. 3C, a SiO₂ film was further deposited in a thickness of 100 nm by the sputtering method and patterning was performed to obtain a gate insulating film 206. Finally, as shown in FIG. 3D, Ti and Au were deposited in thicknesses of 10 nm and 40 nm, respectively, and patterning was performed, to thereby form a gate electrode 207. The TFT had a length of 10 μm and a width of 20 μm. Thus, a field effect n-channel TFT was produced.

The TFT exhibited characteristics of a field effect mobility of 10 cm²V⁻¹s⁻¹, a threshold voltage of -1 V, and an on/off ratio of a value having about four orders or more.

### Example 3

The above-mentioned light control elements and thin film transistors are arranged two-dimensionally. For example, 7,425×1,790 light control elements each having an area of about 30 μm×115 μm including the TFT are arranged in a square array at pitches of 40 μm in a direction of shorter side and 120 μm in a direction of longer side, respectively, which uses the light reflectance control element or light transmittance control element of Example 1. In addition, 1,790 gate wirings penetrating the gate electrodes of the 7,425 TFT's are arranged in the direction of the longer side. Then, 7,425 signal wirings penetrating the portions of the source electrodes of the 1,790 TFT's extending from the island of the amorphous oxide semiconductor film by 5 μm are arranged. The respective wirings are connected to a gate driver circuit and a source driver circuit. Further, color filters each having the same size as that of each light control element is arranged on a surface thereof so that red (R), green (G), and blue (B) color filters are repeated in the direction of the longer side. Thus, an A4-size active matrix color display at about 211 ppi can be constituted.

In the light control device using the light-emitting element of Example 1 as well, among the four TFT's contained in one light control device, the gate electrode of a first TFT is wired to a gate line and the source electrode of a second TFT is wired to a signal line. Further, the light emission wavelengths of light-emitting elements are arranged so that red (R), green (G), and blue (B) light-emitting elements are repeated in the direction of the longer side, thereby making it possible to constitute a light-emitting color display having the same resolution.

In this case, a driver circuit for driving an active matrix may be constituted by using the TFT according to this example which is the same as a TFT of a pixel, or an existing IC chip may be used for the circuit.

### Applications

The above-mentioned display is provided with a device essential to a broadcasting dynamic display apparatus such as a broadcasting receiving device or a voice and image processing device, and the resultant is included in a thin casing together with a power source and an interface. Thus, a broadcasting dynamic display apparatus having a light weight, a thin thickness, and high safety with respect to falling and an impact is provided.

Further, the above-mentioned display is connected to a device essential to a digital information processing apparatus such as a central processor, a storage device, or a network device, and the resultant is included in a thin casing together with a power source and an interface. Thus, an integrated digital information processing apparatus having a light weight, a thin thickness, and high portability is provided.

Further, the area and number of light control elements of the above-mentioned display are reduced to about 2 to 5 inches in a diagonal line. Then, the display is connected to a device essential to a portable information equipment such as a processor, a storage device, or a network device, and the resultant is included in a small and thin casing together with a power source and an interface. Thus, a portable information device having a light weight, a small size, a thin thickness, and high safety with respect to falling and an impact is provided.

Further, a similar small display is connected to a device essential to an image pickup device such as an imaging device, a storage device, or a signal processing device, and the resultant is included in a small and light weight casing together with a power source and an interface. Thus, an image pickup device having a light weight, a small size, and high safety with respect to falling and an impact is provided.

Further, oppositely, the display in which the size of one light control element is enlarged and the display area of which is enlarged is attached to or incorporated into any one of the above-mentioned building structures, thereby providing a building structure capable of displaying an arbitrary image.

Further, the display is incorporated as any one of the above-mentioned structures for movable bodies, thereby providing a structure for a movable body capable of displaying an arbitrary image.

Further, the display is incorporated as a part of any one of the advertising devices, thereby providing an advertising device capable of displaying an arbitrary image.

The light control device and the image display according to the present invention can be used in a wide variety of applications including a broadcasting dynamic image display apparatus, a digital information processing apparatus, a portable information device, an image pickup device, a building structure, a structure for a movable body, and an advertising device each of which has a light weight, a thin thickness, and high safety with respect to breakage.

According to the present invention, the semiconductor region of the thin film transistor and the electrode of the light control device can be produced in the same step, whereby the number of steps is reduced. As a result, it is possible to improve an yield and reduce production costs. In addition, the amount of metal materials to be used for the electrode is reduced, thereby making it possible to achieve reduction in costs of the device.

Further, a material having high visible light transmission is used as a material for forming the electrode (which may include a storage capacitor electrode), whereby display luminance can be improved or power consumption of the backlight can be suppressed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2006-076842, filed Mar. 20, 2006, and No. 2006-342579, filed Dec. 20, 2006, which are hereby incorporated by reference herein in their entirety.

What is claimed is:

1. A light control device, comprising:
a thin film transistor; and
a light control element including an electrode electrically connected to the thin film transistor,
wherein a semiconductor region of the thin film transistor and the electrode are composed of the same semiconductor layer, and the semiconductor layer comprises an amorphous oxide layer including at least one of In, Ga, and Zn.

2. A light control device according to claim 1, wherein a portion of the semiconductor layer which becomes the electrode has a resistivity lower than a resistivity of the semiconductor region.

3. A light control device according to claim 1, wherein one of hydrogen and deuterium is introduced into the portion of the semiconductor layer which becomes the electrode.

4. A light control device according to claim 1, wherein a resistivity of the portion of the semiconductor layer which becomes the electrode is reduced with irradiation of one of an X-ray and an electron beam.

5. A light control device according to claim 1, wherein the semiconductor region and the electrode are in contact with each other.

6. A light control device according to claim 1, wherein the electrode comprises a storage capacitor electrode for holding electric charges.

7. A light control device according to claim 3, wherein the portion of the semiconductor layer which becomes the electrode has a concentration of one of hydrogen and deuterium being 5×10¹⁹ or more.

8. A light control device according to claim 1, the semiconductor region has an electron carrier concentration of less than 10¹⁸/cm³.

9. A light control device according to claim 1, wherein the light control element comprises an electroluminescent device.

10. A light control device according to claim 1, wherein the light control element is a liquid crystal cell.

11. A light control device according to claim 1, wherein the light control element is an electrophoretic particle cell.

12. A light control device according to claim 11, wherein the electrophoretic particle cell is a cell having a capsule sandwiched between opposing electrodes, the capsule containing a fluid and a particle sealed therein.

13. A light control device according to claim 1, wherein the light control element and the thin film transistor are provided on a flexible resin substrate.

14. A light control device according to claim 1, the light control element and the thin film transistor are provided on a transparent substrate.

15. A light control device according to claim 1, wherein the semiconductor region of the thin film transistor is electrically connected to a wiring at a portion different from a connection portion of the electrode of the semiconductor region of the thin film transistor, and the wiring comprises the semiconductor layer.

16. A light control device according to claim 15, wherein a portion of the semiconductor layer which becomes the wiring has a resistivity lower than a resistivity of the semiconductor region.

17. A light control device according to claim 15, wherein the semiconductor region and the wiring are in contact with each other.

18. A display comprising a plurality of light control devices according to claim 1 which are arranged two-dimensionally.
